(19) United States
(12) Patent Application Publication
(10) Pub. No.: US 2010/0163884 A1
(43) Pub. Date: Jul. 1, 2010

(54) SWITCHING DEVICE STRUCTURE OF ACTIVE MATRIX DISPLAY

(76) Inventor: Hsi-Ming Chang, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/427,760

(22) Filed: Apr. 22, 2009

(30) Foreign Application Priority Data
Dec. 25, 2008 (TW) 097150626

(51) Int. Cl. H01L 29/786

(52) U.S. Cl. 257/66; 257/72; 257/E29.294

(57) ABSTRACT

A switching device structure of active matrix display is provided. The switching device structure includes a substrate, a plurality of switching-device gate connection lines disposed on the substrate along a first direction and a plurality of switching devices disposed on the substrate along the first direction. Each switching device includes a gate electrode electrically connected to the any two adjacent switching-device gate connection lines, and the gate electrode protrudes from at least one side of the switching-device gate connection line along a second direction.

### BACKGROUND OF THE INVENTION

1. Field of the Invention

The present invention relates to a switching device structure of active matrix display, and more particularly, to a switching device structure of active matrix display, which can lower the coupling effect between the switching-device gate line and the drain electrode of the switching device, and that between the switching-device gate line and the source electrode of the switching device.

2. Description of the Prior Art

The active matrix display mainly utilizes electric components such as thin film transistors disposed in a matrix, suitable capacitors and landing pads to drive the liquid crystal pixels and create colorful images. In recent years, in order to maintain the quality assurance of the superior displaying images of the active matrix display, an additional inspection circuit is integrated into the fabrication of the active matrix display. Besides, one end of the inspection circuit is electrically connected to the pixel gate lines and the pixel data lines. Meanwhile, by virtue of providing another end of the inspection circuit with an inspecting signal, the pixel circuit, the pixel gate lines and the pixel data lines of the display can be inspected.

Since the inspection circuit can provide an inspection function for the pixel circuit of the display, all of the pixel scan lines and all of the pixel data lines must be directly connected to a shorting bar when performing an inspection. For this reason, after the inspection procedure, the laser cutting method accordingly has to be carried out for disconnecting each of the pixel scan lines and each of the pixel data lines. Alternatively, the shorting bar electrically connected to each of the pixel scan lines and each of the pixel data lines can be removed by virtue of grinding away the edge of the liquid crystal display panel. Otherwise, the display can not operate normally. However, all of the aforementioned methods have disadvantages such as cost increase and low product yield. For example, the laser cutting method is not only time-consuming but also excessively expensive. Beside, the grinding method increases the cost, and is not applicable to a dual display panel in which data lines are shared.

Currently, a switching method which implements selection between display operation and inspection has been developed, i.e. switching devices e.g. thin film transistors are disposed between the shorting bar and the pixel scan lines/pixel data lines. When the inspection of the display is performed, each of the switching devices is turned on so as to allow the inspecting signals coming from the shorting bar to be delivered to each of the pixel scan lines and each of the pixel data lines for inspection. On the contrary, when the display works in normal mode, the switching devices are turned off so that each of the scan lines and each of the data lines are electrically disconnected to each other.

With reference to FIG. 1, FIG. 1 is a schematic top view diagram illustrating a conventional switching device structure of active matrix display. As illustrated in FIG. 1, a conventional switching device structure 10 includes a substrate 11, a switching-device gate line 12 disposed along the first direction X, a plurality of first switching devices 14a and a plurality of second switching devices 14b. The switching-device gate line 12 is served as a gate electrode for both of the first switching devices 14a and the second switching devices 14b. Each of the first switching devices 14a includes a drain electrode 20a and a source electrode 22a, and each of the second switching devices 14b includes a drain electrode 20b and a source electrode 22b. The drain electrode 20a of the first switching device 14a and the drain electrode 20b of the second switching device 14b are respectively connected to the pixel gate lines or the pixel data lines of the display region (not shown in the figure) along the second direction Y. The source electrode 22a of the first switching device 14a and the source electrode 22b of the second switching device 14b are respectively electrically connected to a first shorting bar 24a and a second shorting bar 24b along the second direction Y. Besides, the switching-device gate line 12 is strip shape, and both the length of the overlapping area of the switching-device gate line 12 and the source electrodes 22a, 22b and that of the switching-device gate line 12 and the drain electrodes 20a, 20b are identical to the channel width 26 of the first switching device 14a and the second switching device 14b.

Generally speaking, the first switching devices 14a and the second switching devices 14b are disposed on the side edge of the display. In order to ensure that inspecting signals can be delivered to each of the pixels for performing an inspection procedure, the inspecting signal input is supposed to have enough amperage to drive each of the pixel transistors for carrying out the inspection procedure. However, in order to ensure that the input amperage applied on the display is large enough, the channel width of the switching device should be broadened to increase the amperage limitation of the switching device so as to enable the inspecting signal to have enough amperage and be delivered to each of the pixels. In the aforementioned conventional switching device structure, the increase of the channel width 26 of both the first switching device 14a and the second switching device 14b stands for the increase of the width of the switching-device gate line 12. Since the increase of the width of the switching-device gate lines 12 results in the increase of the overlapping area of the switching-device gate lines 12 and the drain electrodes 20a, 20b and that of the switching-device gate lines 12 and the source electrodes 22a, 22b, the coupling capacitances between the switching-device gate line 12 and the drain electrodes 20a, 20b and those between the switching-device gate line 12 and the source electrodes 22a, 22b will increase with ease. In such a case, an undesired coupling effect will be generated. In other words, when the inspecting signals are imported to the first shorting bar 24a but not imported to the second shorting bar 24b, the inspecting signals passing the source electrodes 22a and the drain electrodes 20a of the first switching device 14a will generate a coupling signal in the second switching device 14b via the switching-device gate line 12 due to the coupling effect. In such a case, the second shorting bar 24b electrically connected to the second switching device 14b will receive the wrong signals. Therefore, the coupling effect between the switching-device gate line 12 and the drain electrodes 20a, 20b and that between the switching-device gate line 12 and the source electrodes 22a, 22b will influence the inspection results of different pixel data lines and different pixel gate lines.

Additionally, in order to form small-scale displays nowadays, the switching devices and the shorting bars are designed to dispose on the same side of the display, and the distances between the switching devices are accordingly shortened. However, the shortened distance will result in occurrence of the coupling effect between the switching devices and result in the incorrect inspection results.

Form aforementioned description we know, to impede the coupling effect between the gate line and the source electrodes, the coupling effect between the gate line and the drain electrodes, and the coupling effect between the switching devices has become an important object to achieve for the industry.

### SUMMARY OF THE INVENTION

It is therefore one object of the present invention to provide a switching device structure of active matrix display to lower the coupling effect between the switching-device gate line and the drain electrodes of the switching devices, the coupling effect between the switching-device gate line and the source electrodes of the switching devices, and the coupling effect between the switching devices.

To achieve the above-mentioned purpose, the present invention discloses a switching device structure of active matrix display. The switching device structure of active matrix display includes a substrate, a plurality of switching-device gate connection lines disposed on the substrate along a first direction, and a plurality of switching devices disposed on the substrate along the first direction. Each of the switching devices includes a gate electrode, a gate insulating layer covering the gate electrode and the substrate, a semiconductor layer disposed on the gate insulating layer, a drain electrode and a source electrode disposed on the semiconductor layer and the gate insulating layer along a second direction. The gate electrode is electrically connected to two adjacent switching-device gate connection lines, the gate electrode protrudes from at least one side of the switching-device gate connection lines along the second direction, and the drain electrodes and source electrodes are respectively corresponding to the two opposite sides of the gate electrode.

To achieve the above-mentioned purpose, the present invention discloses a switching device structure of active matrix display. The switching device structure of active matrix display includes a substrate, a plurality of switching-device gate lines disposed on the substrate and a plurality of the switching devices disposed on the substrate along a first direction. The switching-device gate lines are respectively disposed along a first direction and parallel to each other, and each of the switching devices includes a gate electrode. Each of the gate electrodes is respectively electrically connected to the switching-device gate line. Any two of the switching devices adjacent to each other are disposed on the two opposite sides of one of the switching-device gate lines.

The present invention has the gate electrodes of the switching devices protruding from at least one side of the switching-device connection lines along a direction, therefore reducing the overlapping area of the switching-device gate line and the drain electrode of the switching device and that of the switching-device gate line and the source electrode of the switching device. In addition, each of the switching devices can be individually isolated by virtue of arranging the switching-device gate line so as to increase the distances between the switching devices. In such a case, the coupling effect between the switching-device gate line and the drain electrodes of the switching devices, the coupling effect between the switching-device gate line and the source electrodes of the switching devices, and the coupling effect between the switching devices can be lowered.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view diagram illustrating a switching device structure of active matrix display.

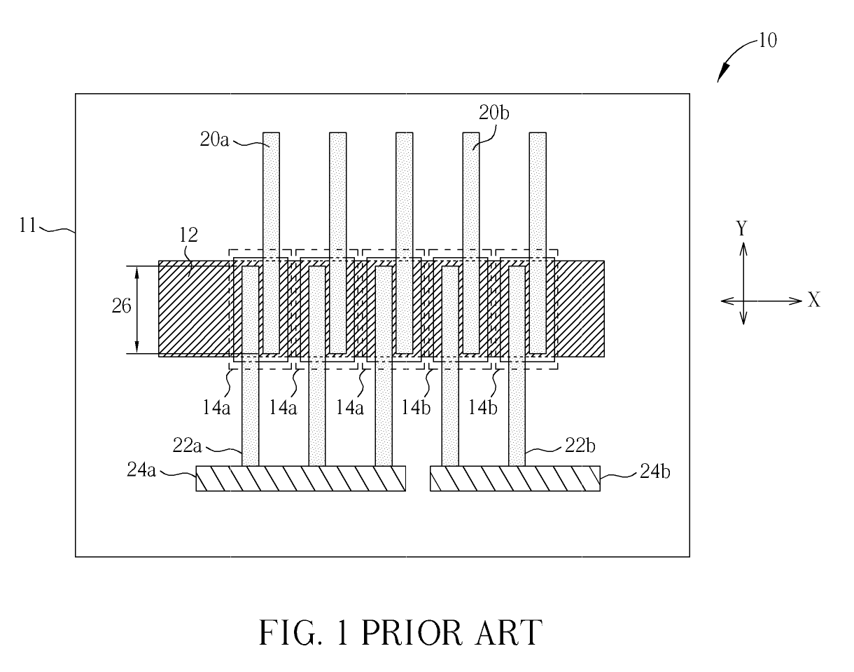

FIG. 2 is a schematic top view diagram illustrating a switching device structure of active matrix display of the first embodiment of the present invention.

FIG. 3 is a schematic cross-sectional diagram illustrating a switching device structure illustrated in FIG. 2 along the tangent line AA′.

FIG. 4 is a schematic top view diagram illustrating a switching device structure of active matrix display of the second embodiment of the present invention.

FIG. 5 is a schematic top view diagram illustrating a switching device structure of active matrix display of the third embodiment of the present invention.

FIG. 6 is a schematic top view diagram illustrating a switching device structure of active matrix display of the fourth embodiment of the present invention.

FIG. 7 is a schematic top view diagram illustrating a switching device structure of active matrix display of the fifth embodiment of the present invention.

FIG. 8 is a schematic top view diagram illustrating a switching device structure of active matrix display of the sixth embodiment of the present invention.

FIG. 9 is a schematic top view diagram illustrating a switching device structure of active matrix display of the seventh embodiment of the present invention.

### DETAILED DESCRIPTION

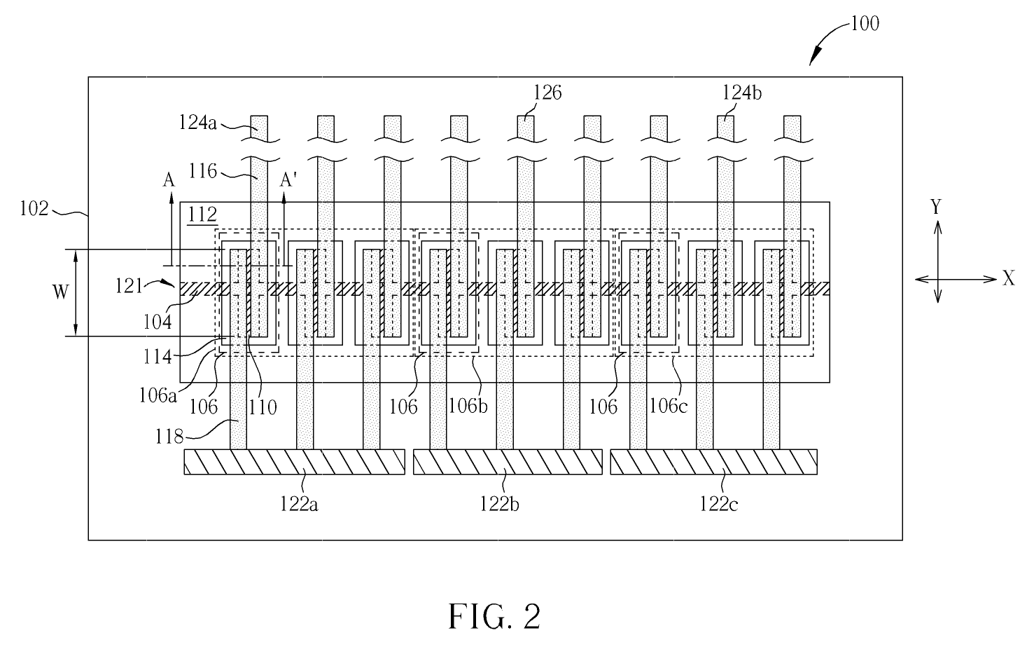

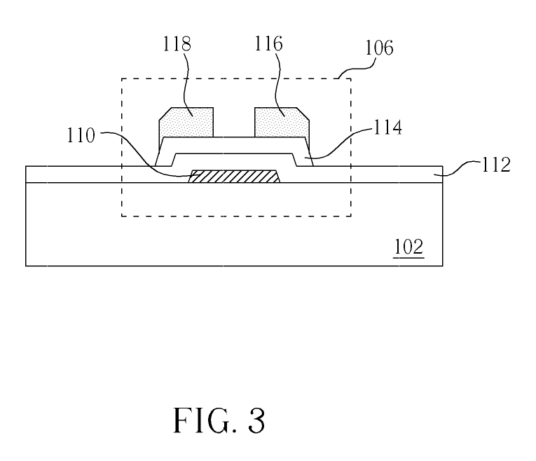

With reference to FIG. 2 and FIG. 3, FIG. 2 is a schematic top view diagram illustrating a switching device structure of active matrix display of the first embodiment of the present invention, and FIG. 3 is a schematic cross-sectional diagram illustrating a switching device structure illustrated in FIG. 2 along the tangent line AA′. As illustrated in FIG. 2, a switching device structure 100 of active matrix display of the present invention includes a substrate 102, a plurality of switching-device gate connection lines 104 and a plurality of switching devices 106. The switching-device gate connection lines 104 are disposed on the substrate 102 along a first direction X, and the switching devices 106 are also disposed on the substrate 102 along the first direction X. As illustrated in FIG. 3, each of the switching devices 106 includes a gate electrode 110, a gate insulating layer 112, a semiconductor layer 114, a drain electrode 116 and a source electrode 118. The gate electrodes 110 and the switching-device gate connection lines 104 are in the same metal layer, and the gate electrodes 110 are disposed along the first direction X. In addition, each of the gate electrodes 110 is electrically connected to two adjacent switching-device gate connection lines 104, and each of the gate electrodes 110 protrudes from at least one side of the switching-device gate connection lines 104 along a second direction Y. The gate insulating layer 112 covers the gate electrodes 110, a part of the switching-device gate connection lines 104 and the substrate 102, and the semiconductor layer 114 is disposed on the gate insulating layer 112. Each of the drain electrode 116 is respectively disposed on the semiconductor layer 114 and the gate insulating layer 112 along the second direction Y, each of the source electrode 118 is respectively disposed on the semiconductor layer 114 and the gate insulating layer 112 along the second direction Y, and each of the drain electrodes 116 and each of the source electrodes 118 are respectively corresponding to the two opposite sides of the gate electrode 110.

In this embodiment, the switching-device gate connection lines 104 are connected to each other to form a switching-device gate line 121, and each of the gate electrodes 110 is connected to the two opposite sides of the switching-device gate connection lines 104 along the second direction Y so that the switching-device gate lines 104 and each of the gate electrodes 110 can form a cross shape. The channel width W of the switching device 106 is identical to the distance between the two opposite sides of each of the gate electrode 110 protruding the two opposite sides of the switching-device gate line 121 along the second direction Y. It should be noted that since each of the gate electrodes 110 protrudes from the two opposite sides of the switching-device gate line 121 along the second direction Y, the channel width W of the switching device 106 is not limited to the width of the switching-device gate line 121. Consequently, the channel width W of the switching device 106 can be moderately adjusted according to the length of the protruding portion of the gate electrode 110 along the second direction Y. In such a case, even if the channel width W of the switching device 106 is unchanged, the width of the switching-device gate line 121 of the present invention still can be reduced so as to lower the overlapping area of the switching-device gate line 121 and the drain electrodes 116 and the overlapping area of the switching-device gate line 121 and the source electrodes 118. Consequently, the coupling capacitance between the switching-device gate lines 104 and the drain electrodes 116 and the coupling capacitance between the switching-device gate lines 104 and the source electrodes 118 can be reduced so as to lower the coupling capacitance therebetween.

In this embodiment, the switching device structure 100 further includes a first shorting bar 122a, a second shorting bar 122b and a third shorting bar 122c. Furthermore, the switching devices 106 can be divided into the first switching-device components 106a, the second switching-device components 106b and the third switching-device components 106c. The source electrode 118 of the first switching-device component 106a toward the second direction Y is electrically connected to the first shorting bar 122a, the source electrode 118 of the second switching-device component 106b toward the second direction Y is electrically connected to the second shorting bar 122b, and the source electrode 118 of the third switching-device component 106c toward the second direction Y is electrically connected to the third shorting bar 122c. On the other hand, the drain electrode 116 of each of the first switching-device component 106a toward the second direction Y is electrically connected to one corresponding even-numbered pixel gate line 124a, the drain electrode 116 of each of the second switching-device component 106b toward the second direction Y is electrically connected to one corresponding pixel data lines 126, and the drain electrode 116 of each of the third switching-device component 106c toward the second direction Y is electrically connected to one corresponding odd-numbered pixel gate lines 124b. In such a case, the even-numbered pixel gate lines 124a, the pixel data lines 126 and the odd-numbered pixel gate lines 124b can be electrically connected to the first shorting bar 122a, the second shorting bar 122b and the third shorting bar 122c respectively. Furthermore, the pixel gate lines 124a, 124b and the pixel data lines 126 can be inspected by virtue of providing the first shorting bar 122a, the second shorting bar 122b and the third shorting bar 122c with an inspection signal. When an inspection procedure is performed, a trigger signal is applied to the switching-device gate line 121 firstly so as to switch on each of the switching devices 106. Afterwards, the inspection signals are respectively imported into the first shorting bar 122a, the second shorting bar 122b and the third shorting bar 122c so as to check whether each of the pixels of the display can work normally or not. It should be noted that since the overlapping area of the switching-device gate line 121 and the drain electrode 116 and the overlapping area of the switching-device line 121 and the source electrode 118 can be lowered in this embodiment, the coupling effect with respect to pixel data lines 126 and odd-numbered pixel gate lines 124b can be lowered when inspecting signals imported into the first shorting bar 122a for inspecting even-numbered pixel gate lines 124a. In such a case, incorrect signals will not be created. Similarly, since the overlapping area of the switching-device gate line 121 and the drain electrode 116 and the overlapping area of the switching-device line 121 and the source electrode 118 can be lowered in this embodiment, the coupling effect with respect to other pixel gate electrode lines 124a, 124b or the pixel data line 126 can be lowered when inspecting the pixel data lines 126 or odd-numbered pixel gate electrodes 124b.

Besides, the present invention is not limited to the aforementioned three shorting bars, and the switching-device structure can have at least a shorting bar electrically connected to the source electrode 118 of each of the switching devices 106. Namely, the pixel data lines 126, the even-numbered pixel gate lines 124a and odd-numbered pixel gate lines 124b can be inspected by the same shorting bar. However, the numbers of the shorting bars can be increased in the present invention as required so as to enhance the inspection function mainly according to the pixel data lines 126 or the pixel gate lines 124a, 124b respectively having different functions or positions. For instance, the pixel data lines can be divided into red sub pixel data lines, green sub pixel data lines and blue sub pixel data lines. Consequently, all of the red sub pixel data lines can be connected to a red sub-pixel shorting bar, all of the green sub pixel data lines can be connected to a green sub-pixel shorting bar, and all of the blue sub-pixel data lines can be connected to a blue sub-pixel shorting bar. However, the present invention is not limited thereto.

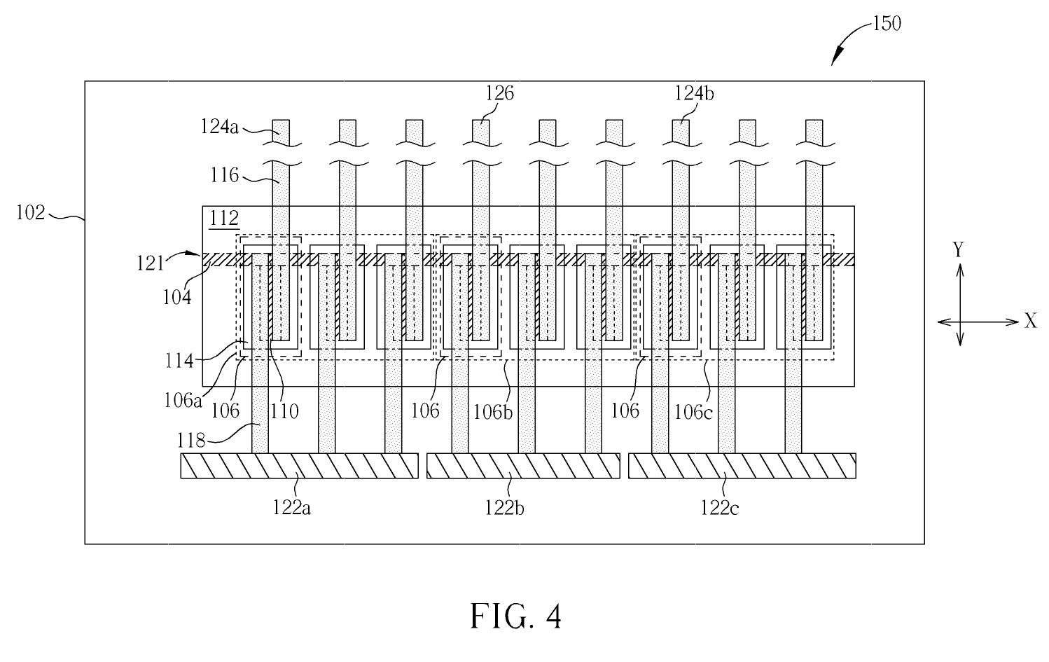

In addition, the layout and arrangement of the switching-device gate connection lines and the gate electrodes of the present invention are not limited thereto. The overlapping area of the switching-device gate line and the drain electrode and the overlapping area of the switching-device gate line and the source electrode can be efficiently reduced so as to moderately adjust the pattern arrangement of the switching-device gate connection lines and the gate electrodes. In order to compare the difference between each of the embodiments with ease, identical components are denoted by identical numerals in the following embodiments and the first embodiment. With reference to FIG. 4, FIG. 4 is a schematic top view diagram illustrating a switching device structure of active matrix display of the second embodiment of the present invention. As illustrated in FIG. 4, compared with the first embodiment, each of the gate electrodes 110 of the switching device structure 150 of this embodiment is connected to one side of the switching-device gate line 121 along the second direction Y so that the switching device structure and each of the gate electrodes 110 can form a T shape.

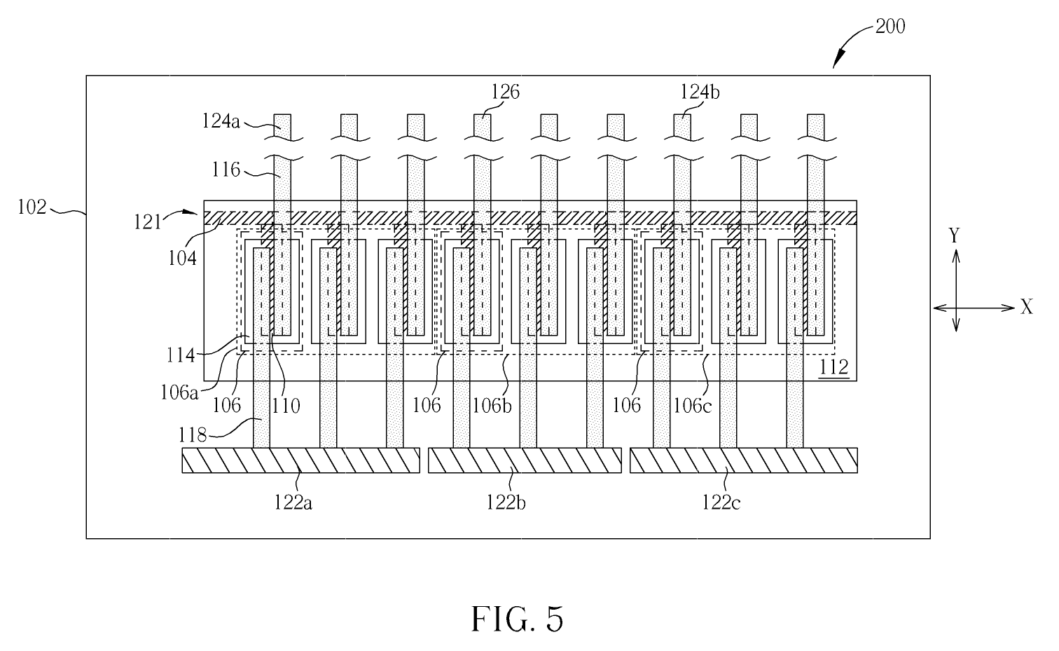

With reference to FIG. 5, FIG. 5 is a schematic top view diagram illustrating a switching device structure of active matrix display of the third embodiment of the present invention. As illustrated in FIG. 5, each of the gate electrodes 110 of the switching device structure 200 of this embodiment is connected to one side of the switching-device gate line 121 along the second direction Y so that the switching-device gate line 121 and each of the gate electrodes 110 can form a T shape. However, the difference between this embodiment and the switching device structure 150 of the second embodiment is in that the switching-device gate line 121 of this embodiment does not overlap with the source electrode 118 and only partially overlaps with the drain electrode 116 of each of the switching devices 106. Therefore, compared with the switching device structure 150 of the second embodiment, the overlapping area of the switching-device gate line 121 and the source electrode 118 and the overlapping area of the switching-device gate line 121 and the drain electrode 116 can be efficiently reduced so as to efficiently reduce the coupling effect. Besides, the arrangement that the switching-device gate line 121 of the present invention can not overlap with the drain electrode and partially overlap with the source electrode is not limited. On the contrary, the switching-device gate line 121 of the present invention can partially overlap with the drain electrode and not overlap with the source electrode.

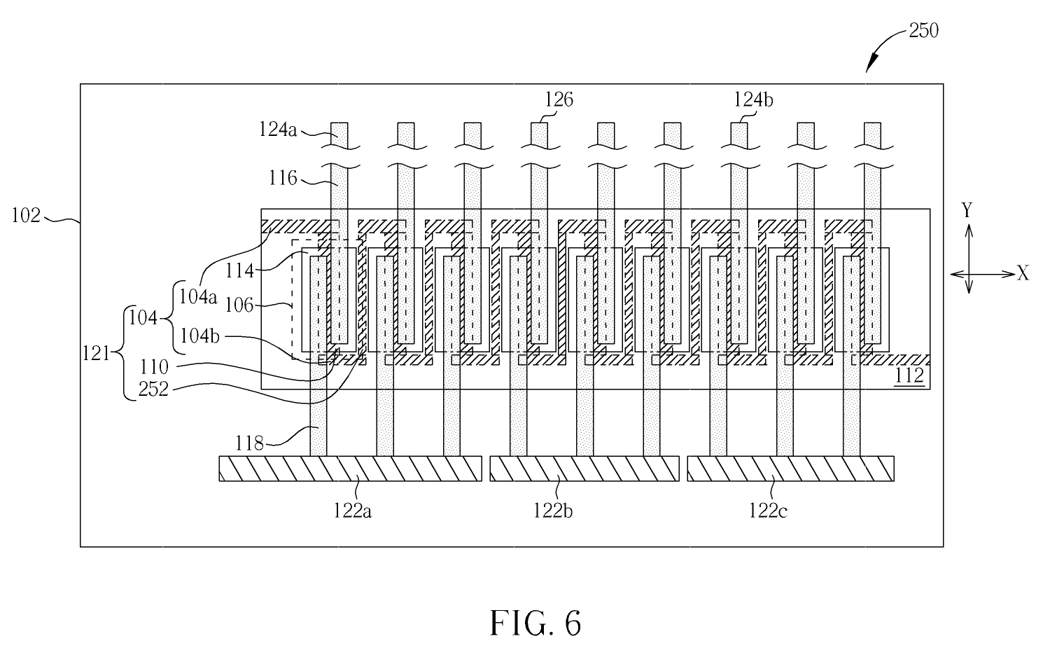

With reference to FIG. 6, FIG. 6 is a schematic top view diagram illustrating a switching device structure of active matrix display of the fourth embodiment of the present invention. As illustrated in FIG. 6, compared with the first embodiment, the switching-device gate connection lines 104 of the switching device structure 250 of this embodiment includes a plurality of first switching-device gate connection lines 104a and a plurality of second switching-device gate connection lines 104b. The first switching-device gate connection lines 104a and the second switching-device gate connection lines 104b are disposed parallel to each other along the first direction X. Besides, the switching-device structure 250 of this embodiment further includes a plurality of connection lines 252, and the connection lines 252 are disposed between and connected to the corresponding first switching-device gate connection lines 104a and the second switching-device connection lines 104b along the second direction Y. Each of the connection lines 252 and each of the gate electrodes 106 are disposed alternately along the first direction X. Each of the first switching-device gate connection lines 104a, each of the gate electrodes 106, each of the second switching-device connection lines 104b and each of the connection lines 252 are electrically connected to each other in series so as to form a switching-device gate line 121. From aforementioned description we know, the switching-device gate connection lines 104a and the connection lines 252 in this embodiment have less overlapping area with the source electrode 118 and the drain electrode 116 of the switching device 106. In such a case, the coupling effect between the switching-device gate lines 104 and the source electrodes 118 and the coupling effect between the switching-device gate lines 104 and the drain electrodes 116 can be efficiently avoided.

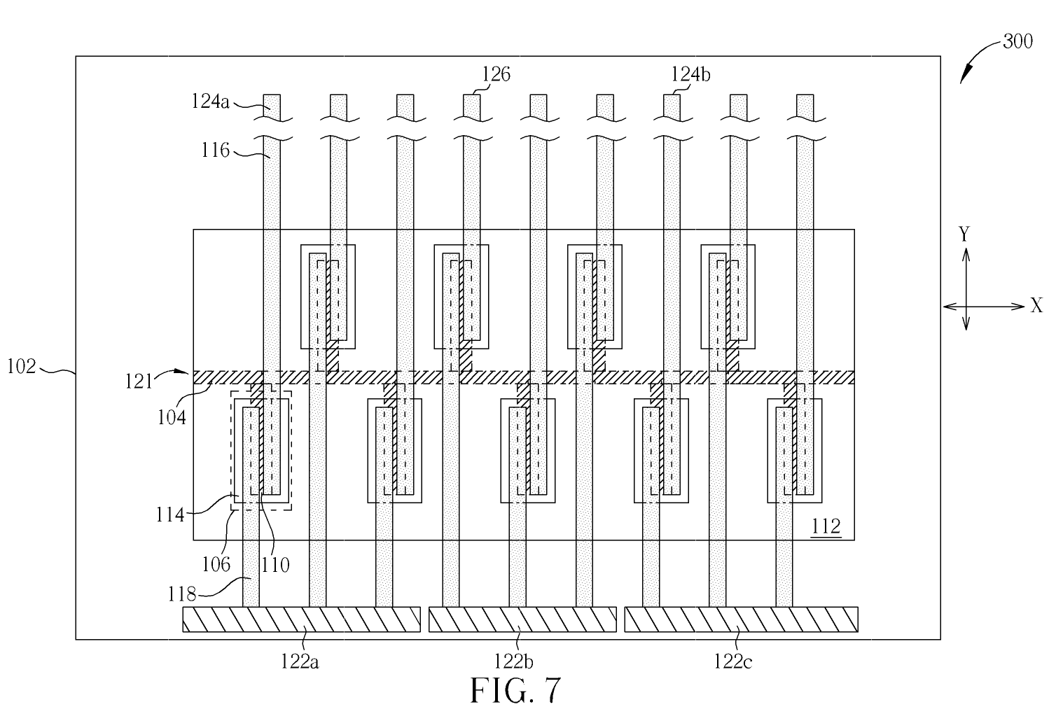

With reference to FIG. 7, FIG. 7 is a schematic top view diagram illustrating a switching device structure of active matrix display of the fifth embodiment of the present invention. As illustrated in FIG. 7, compared with the first embodiment, any two of the gate electrodes 110 adjacent to each other of the switching device structure 300 of this embodiment respectively extend along the second direction Y and are connected to the two opposite sides of the switching-device gate line 121. It is therefore that the gate electrodes 110 are disposed alternately on the two opposite sides of the switching-device gate line 121 along the first direction X. In such a case, the switching devices 106 can be alternately disposed on the two opposite sides of the switching-device gate line 121 so that the coupling effect between any two excessively adjacent switching devices 106 can be avoided. Besides, the switching-device gate line 121 of this embodiment only partially overlaps with the source electrode 118 of each of the switching devices 106 and partially overlaps with the drain electrode 116 of each of the switching-device gate line 121. Consequently, the coupling effect between the switching-device gate line 121 and the source electrode 118 and the coupling effect between the switching-device gate line 121 and the drain electrode 116 can be efficiently reduced.

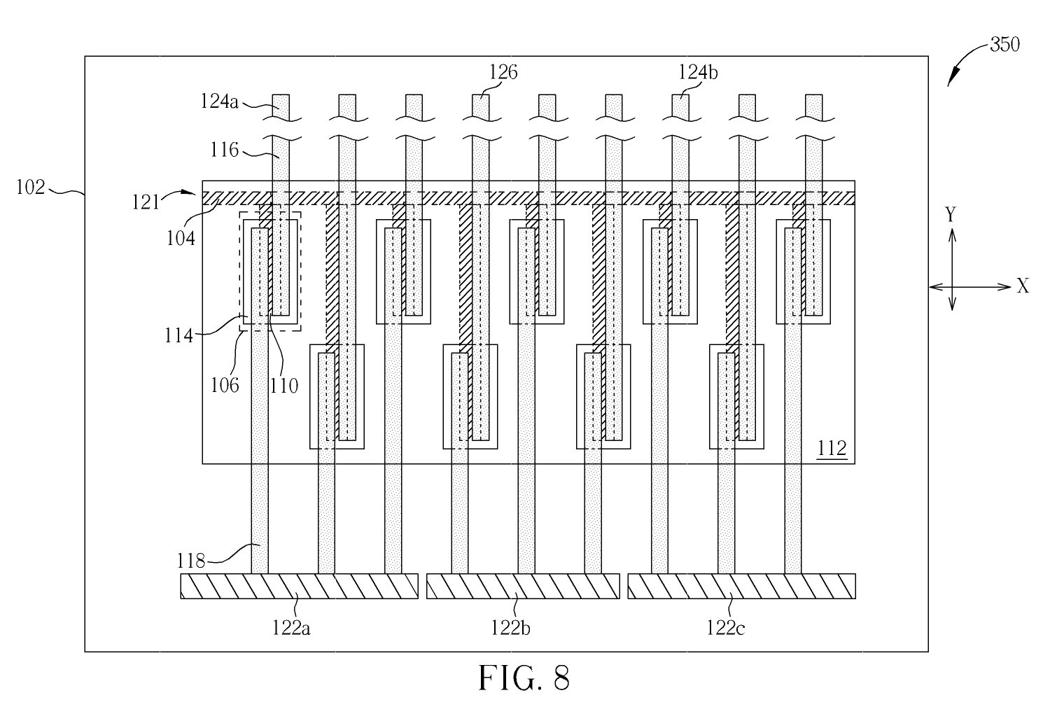

With reference to FIG. 8, FIG. 8 is a schematic top view diagram illustrating a switching device structure of active matrix display of the sixth embodiment of the present invention. As illustrated in FIG. 8, each of the gate electrodes 110 of the switching device structure 350 of this embodiment is connected to one side of the switching-device gate line 121 along the second direction Y so that the switching-device gate line 121 and each of the gate electrodes 110 can form a T shape. Consequently, any two of the gate electrodes 110 adjacent to each other have different lengths individually so that the coupling effect between two adjacent switching devices 106 due to excessively short distance can be avoided.

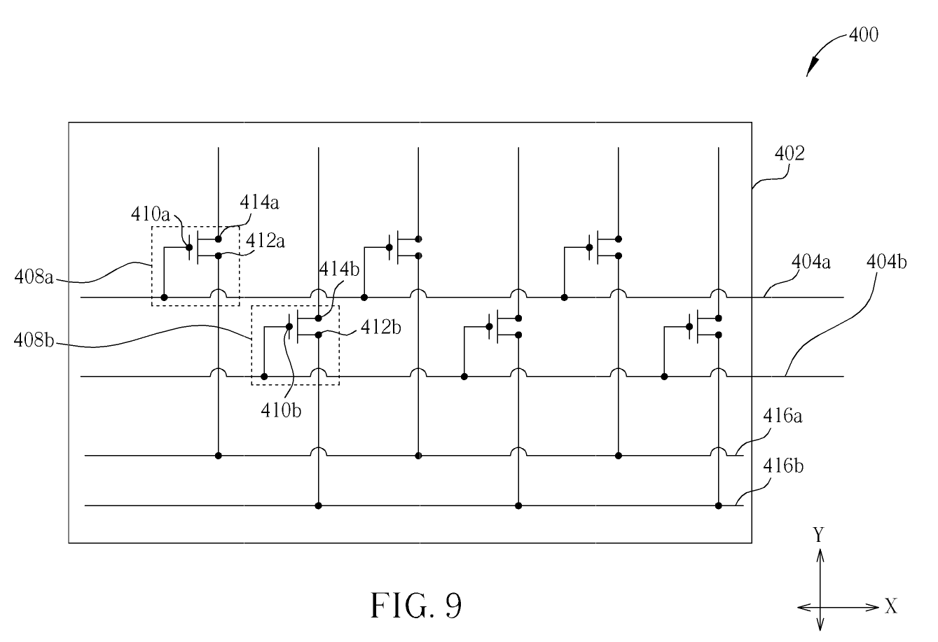

Besides, the switching device structure of active matrix display is not limited to the aforementioned embodiment, which includes only one switching-device gate line, and the switching device structure of active matrix display can include a plurality of switching-device gate lines. In addition, since the aforementioned embodiment has illustrated the arrangement of the single switching-device gate line and the arrangement of the gate electrodes of the switching devices, the arrangement of the switching-device gate line and the gate electrodes of the switching devices are no longer detailed for succinctness. With reference to FIG. 9, FIG. 9 is a schematic top view diagram illustrating a switching device structure of active matrix display of the seventh embodiment of the present invention. As illustrated in FIG. 9, the switching device structure 400 of this embodiment includes a substrate 402, a first switching-device gate line 404a disposed on the substrate 402, a second switching-device gate line 404b disposed on the substrate 402, a plurality of first switching devices 408a and a plurality of second switching devices 408b disposed on the substrate 402 along the first direction X. The first switching-device gate lines 404a and the second switching-device gate lines 404b are disposed parallel to each other along the first direction X. Each of the first switching devices 408a includes a first gate electrode 410a, a first source electrode 412a and a first drain electrode 414a, and each of the second switching devices 408b includes a second gate electrode 410b, a second source electrode 412b and a second drain electrode 414b. The first gate electrode 410a and the second gate electrode 410b are electrically connected to the first switching-device gate line 404a and the second switching-device gate line 404b respectively. It should be noted that each of the first switching devices 408a and each of the second switching devices 408b are disposed alternately along the first direction X, and the first switching devices 408a and the second switching devices 408b are respectively disposed on the two opposite sides of the first switching-device gate line 404a so that the first switching devices 408a and the second switching devices 408b are separated into two divisions with respect to the first switching gate line 404a by virtue of the arrangement of the first switching gate line 404a. In such a case, the distance between any two of the first switching devices 408a and the second switching devices 408b adjacent to each other can be increased so that the coupling effect between the first switching device 408a and the second switching device 408b adjacent to each other can be avoided. However, the arrangement of the first switching devices 408a and the second switching devices 408b of the present invention disposed on the two opposite sides of the first switching-device gate line 404a is not limited, and the first switching devices 408a and the second switching devices 408b can be disposed on the two opposite sides of the second switching-device gate line 404b respectively. However, any two of the first switching devices 408a and second switching devices 408b adjacent to each other are respectively disposed on the two opposite sides of the first switching-device gate line 404a or the second switching-device gate line 404b. Besides, the present invention having two switching-device gate lines is not limited thereto. However, the present invention can have at least a switching-device gate line. In such a case, the numbers of the switching-device gate lines can be increased or reduced as required.

In addition, in this embodiment, the switching device structure 400 further includes a first shorting bar 416a and a second shorting bar 416b, and the first source electrode 412a and the second source electrode 412b are electrically connected to the first shorting bar 416a and the second shorting bar 416b respectively. However, the present invention having two shorting bars is not limited thereto, and the switching device structure can have at least a shorting bar. It should be noted that the numbers of the shorting bar can be increased for performing an inspection procedure as required according to different functions, positions or the function of the switching-device gate line.

In summary, the present invention provides a gate electrode of the switching device protruding from at least one side of the switching-device gate connection lines along one direction and reduces the overlapping area of the switching-device gate line and the drain electrode of the switching device and the overlapping area of the switching-device gate line and the source electrode of the switching device so as to efficiently lower the coupling effect between the switching-device gate line and the drain electrode of the switching device and the coupling effect between the switching-device gate line and the source electrode of the switching device. In addition, each of the switching devices of the present invention can be individually isolated by virtue of arranging the switching-device gate line or be apart from any two adjacent switching devices so that the distance between any two adjacent switching devices can be increased. Therefore, the coupling effect between the switching devices can be avoided.

Those skilled in the art will readily observe that numerous modifications and alterations of the device and method may be made while retaining the teachings of the invention.

What is claimed is:

1. A switching device structure of active matrix display, comprising:
a substrate;
a plurality of switching-device gate connection lines disposed on the substrate along a first direction; and
a plurality of switching devices disposed on the substrate along the first direction, each of the switching devices comprising:
a gate electrode electrically connected to the two adjacent switching-device gate connection lines, the gate electrode protruding from at least one side of the switching-device gate connection line along a second direction;
a gate insulating layer covering the gate electrode and the substrate;
a semiconductor layer disposed on the gate insulating layer;
a drain electrode disposed on the gate insulating layer along the second direction; and
a source electrode disposed on the gate insulating layer along the second direction, the drain electrode and the source electrode respectively corresponding to two opposite sides of the gate electrode.

2. The switching device structure of active matrix display of claim 1, wherein the switching-device gate connection lines are connected to each other to form a switching-device gate line.

3. The switching device structure of active matrix display of claim 2, wherein each of the gate electrodes is connected to two opposite sides of the switch-device gate line along the second direction.

4. The switching device structure of active matrix display of claim 2, wherein each of the gate electrodes is connected to one side of the switch-device gate line along the second direction.

5. The switching device structure of active matrix display of claim 4, wherein any two of the switching devices adjacent to each other respectively have different distances with respect to the switching-device gate line.

6. The switching device structure of active matrix display of claim 2, wherein any two of the gate electrodes adjacent to each other are respectively connected to two opposite sides of the switching-device gate line along the second direction.

7. The switching device structure of active matrix display of claim 1, wherein the switching-device gate connection lines comprise a plurality of first gate connection lines and a plurality of second gate connection lines, and the first gate connection lines and the second gate connection lines are disposed parallel to each other along the first direction.

8. The switching device structure of active matrix display of claim 7, further comprising a plurality of connection lines electrically connected to and disposed between the corresponding first gate connection lines and the corresponding second gate connection lines along the second direction.

9. The switching device structure of active matrix display of claim 8, wherein each of the connection lines and each of the gate electrodes are disposed alternately along the first direction, and the connection lines, the gate electrodes, the first gate connection lines and the second gate connection lines are electrically connected in series.

10. The switching device structure of active matrix display of claim 1, further comprising at least a shorting bar electrically connected to the source electrodes.

11. The switching device structure of active matrix display of claim 10, wherein the drain electrodes are electrically connected to a plurality of pixel data lines.

12. The switching device structure of active matrix display of claim 10, wherein the drain electrodes are electrically connected to a plurality of pixel gate lines.

13. A switching device structure of active matrix display, comprising:
a substrate;
a plurality of switching-device gate lines disposed on the substrate, the switching-device gate lines being disposed along the first direction and parallel to each other; and
a plurality of switching devices disposed on the substrate, each of the switching devices comprising a gate electrode, and the gate electrodes respectively being electrically connected to the switching-device gate lines, wherein any two of the switching devices adjacent to each other are disposed on two opposite sides of one of the switching-device gate lines.

14. The switching device structure of active matrix display of claim 13, further comprising at least a shorting bar, wherein each of the switching devices comprises a source electrode electrically connected to the shorting bar.
